(19) United States
(12) Patent Application Publication
(10) Pub. No.: US 2015/0013748 A1
(43) Pub. Date: Jan. 15, 2015

(54) MAXIMUM POWER POINT TRACKING (MPPT)

(71) Applicant: Djordje Garabandic, Burnaby (CA)

(72) Inventor: Djordje Garabandic, Burnaby (CA)

(21) Appl. No.: 14/379,030

(22) PCT Filed: Feb. 17, 2012
(86) PCT No.: PCT/US2012/025739

§ 371 Date: Aug. 15, 2014

(51) Int. Cl. G01R 31/40; G01R 21/133

(52) U.S. Cl. CPC H02S 50/00; G01R 21/133
USPC 136/244; 702/60

(57) ABSTRACT

Disclosed are methods, systems, and other implementations, including a method that includes measuring a plurality of samples of power produced by a photovoltaic (PV) array over a first interval of time, determining, based on the measured plurality of samples a non-linear predictive model of a behavior of the power produced by the PV array, and performing a first adjustment of the PV array's voltage at a second time instant subsequent to an end of the first interval of time. The method further includes measuring at a third time instant another sample of the power of the PV array with the adjusted voltage, and determining a power difference between the power of the PV array with the adjusted voltage at the third time instant and a computed power level of the PV array at the third time instant determined from the non-linear predictive model.

### BACKGROUND

The process of converting renewable energy into power is generally complex, as many external factors play a role in how that energy is harvested and utilized. Typically, conditions are analyzed to try to maximize the harvested energy. For example, a solar panel, implemented using a photovoltaic (PV) array(s) can collect more energy when positioned perpendicularly to the sun on a cloudless day. As environmental conditions (e.g., cloud coverage, temperature, angle of irradiation of the sun with the solar panel, etc.) change, power extraction efficiently also changes.

Additionally, power efficiency provided by solar panels generally also varies as load conditions change. Accordingly, in order to properly extract the energy from solar panels in accordance with load conditions, maximum power point tracking procedures may be utilized. The maximum power point tracking (MPPT) procedures may determine the supply and demand of the PV array(s) and the load (e.g., appliances, machines, battery), and may be used to identify the optimal or near optimal voltage/current of the PV array at which power extraction may be maximized (or nearly maximized).

Rapid shifts in insolation conditions (e.g., changing cloud coverage, drop in temperature, changing angle of the sun with respect to the solar panels) may affect MPPT results, possibly causing erroneous MPPT results.

### SUMMARY

Disclosed herein are systems, methods and other implementations that provide efficient realization of maximum power point (MPP) determination that can be achieved in rapidly changing insolation conditions (e.g., environmental conditions, such as cloud coverage, temperature, position of the sun in the sky, etc.)

Thus, in some embodiments, a method for power tracking is disclosed. The method includes measuring a plurality of samples of power produced by a photovoltaic (PV) array over a first interval of time, determining, based on the measured plurality of samples of the power of the PV array, a non-linear predictive model of a behavior of the power produced by the PV array, and performing a first adjustment of the PV array's voltage at a second time instant subsequent to an end of the first interval of time. The method further includes measuring at a third time instant another sample of the power of the PV array with the adjusted voltage, and determining a power difference between the power of the PV array with the adjusted voltage at the third time instant and a computed power level of the PV array at the third time instant determined from the non-linear predictive model.

Embodiments of the method may include at least some of the features described in the present disclosure, including one or more of the following features.

The method may further include performing another adjustment of the voltage of the PV array based on the determined power difference between the power of the PV array with the adjusted voltage at the third time instant and the computed power level of the PV array at the third time instant determined from the non-linear predictive model.

Performing the other adjustment of the voltage of the PV array may include increasing the voltage of the PV array in response to a determination that the power difference is greater than ε when the first adjustment of the voltage of the PV array was a voltage increase, wherein ε is a pre-determined value smaller than power produced by the PV array.

Performing the other adjustment of the voltage of the PV array may include decreasing the voltage of the PV array in response to a determination that the power difference is less than ε when the first adjustment of the voltage of the PV array was a voltage increase, wherein ε is a pre-determined value smaller than power produced by the PV array.

Determining the non-linear predictive model of the behavior of the power produced by the PV array may include deriving the non-linear predictive model using one or more of, for example, interpolation polynomials, a least square technique, and/or trigonometric interpolation.

Measuring the plurality of samples of the power of the PV array over the first interval of time may include measuring the plurality of samples at irregular time periods during the first interval of time.

The non-linear predictive model of the behavior of the power of the PV array may include a non-linear predictive model of the behavior of the power of the PV array resulting from insolation changes.

The insolation changes may include one or more of, for example, a temperature change, a cloud cover change, and/or a sun position change.

In some embodiments, a system is disclosed. The system includes one or more photovoltaic (PV) arrays configured to convert solar irradiation into current, a sampling subsystem to measure one or more samples of power produced by the one or more PV arrays, and a controller. The controller is configured to determine, based on a plurality of samples of the power of the one or more PV array measured over a first time interval, a non-linear predictive model of a behavior of the power produced by the one or more PV arrays, cause a first adjustment of the one or more PV arrays' voltage at a second time instant subsequent to an end of the first interval of time, and determine a power difference between another sample of the power of the one or more PV arrays with the adjusted voltage measured at a third time instant and a computed power level of the one or more PV arrays at the third time instant determined from the non-linear predictive model.

Embodiments of the system may include at least some of the features described in the present disclosure, including at least some of the features described above in relation to the method, as well as one or more of the following features.

The controller may further be configured to cause another adjustment of the voltage of the one or more PV arrays based on the determined power difference between the power of the one or more PV arrays with the adjusted voltage at the third time instant and the computed power level of the one or more PV arrays at the third time instant determined from the non-linear predictive model.

The controller configured to cause the other adjustment of the voltage of the one or more PV arrays may be configured to cause an increase of the voltage of the one or more PV arrays in response to a determination that the power difference is greater than ε when the first adjustment of the voltage of the one or more PV arrays was a voltage increase, wherein ε is a pre-determined value smaller than power produced by the one or more PV arrays.

The controller configured to cause the other adjustment of the voltage of the one or more PV arrays may be configured to cause a decrease of the voltage of the PV array in response to a determination that the power difference is less than ε when the first adjustment of the voltage of the one or more PV arrays was a voltage increase, wherein ε is a pre-determined value smaller than power produced by the one or more PV arrays.

The controller configured to determine the non-linear predictive model of the behavior of the power produced by the one or more PV arrays may be configured to derive the non-linear predictive model using one or more of: interpolation polynomials, a least square technique, and trigonometric interpolation.

The controller may include one or more processors.

The sampling subsystem configured to measure the one or more samples of the power produced by the one or more PV arrays may be configured to measure the plurality of samples at irregular time periods during the first interval of time.

In some embodiments, a method for power tracking is disclosed. The method includes measuring a plurality of samples of power produced by a photovoltaic (PV) array over a first interval of time, determining, based on the measured plurality of samples of the power of the PV array, a non-linear predictive model of a behavior of the power produced by the PV array, and performing a first adjustment of the PV array's current at a second time instant subsequent to an end of the first interval of time. The method further includes measuring at a third time instant another sample of the power of the PV array with the adjusted current, and determining a power difference between the power of the PV array with the adjusted current at the third time instant and a computed power level of the PV array at the third time instant determined from the non-linear predictive model.

Embodiments of the method may include at least some of the features described in the present disclosure, including at least some of the features described above in relation to the first method and the system, as well as one or more of the following features.

The method may further include performing another adjustment of the current of the PV array based on the determined power difference between the power of the PV array with the adjusted current at the third time instant and the computed power level of the PV array at the third time instant determined from the non-linear predictive model.

In some embodiments, a method for power tracking is disclosed. The method includes measuring a plurality of samples of power produced by a photovoltaic (PV) array over a first interval of time, and determining, based on the measured plurality of samples of the power of the PV array, a linear predictive model of a behavior of the power produced by the PV array, the linear predictive model derived using a least square technique. The method further includes performing a first adjustment of the PV array's voltage at a second time instant subsequent to an end of the first interval of time, measuring at a third time instant another sample of the power of the PV array with the adjusted voltage, and determining a power difference between the power of the PV array with the adjusted voltage at the third time instant and a computed power level of the PV array at the third time instant determined from the linear predictive model derived using the least square technique.

Embodiments of the method may include at least some of the features described in the present disclosure, including at least some of the features described above in relation to the methods and the system.

Unless defined otherwise, all technical and scientific terms used herein have the same meaning as commonly or conventionally understood. As used herein, the articles “a” and “an” refer to one or to more than one (i.e., to at least one) of the grammatical object of the article. By way of example, “an element” means one element or more than one element. “About” and/or “approximately” as used herein when referring to a measurable value such as an amount, a temporal duration, and the like, is meant to encompass variations of ±20% or ±10%, ±5%, or +0.1% from the specified value, as such variations are appropriate to in the context of the systems, devices, methods, and other implementations described herein.

As used herein, including in the claims, “and” as used in a list of items prefaced by “at least one of” or “one or more of” indicates that any combination of the listed items may be used. For example, a list of “at least one of A, B, and C” includes any of the combinations A or B or C or AB or AC or BC and/or ABC (i.e., A and B and C). Furthermore, to the extent more than one occurrence or use of the items A, B, or C is possible, multiple uses of A, B, and/or C may form part of the contemplated combinations. For example, a list of “at least one of A, B, and C” may also include AA, AAB, AAA, BB, etc.

Other and further objects, features, aspects, and advantages of the present disclosure will become better understood with the following detailed description of the accompanying drawings.

### BRIEF DESCRIPTION OF THE DRAWINGS

FIG. 1A is a schematic diagram of a solar panel system to harvest solar energy.

FIG. 1B is an example graph of power output behavior for a PV array, such as the PV array shown in FIG. 1A, as a function of the array's voltage

FIG. 2 is a graph of the power behavior of a PV array over a period of time as a result of insolation changes and/or voltage perturbation.

FIG. 3 is a flow chart of a power tracking procedure that takes into account the effect of insolation changes on the power tracking functionality performed by, for example, the system of FIG. 1A.

FIG. 4 is a schematic diagram of an example system implementation to perform a tracking procedure such as the procedure of FIG. 3.

FIG. 5 is a schematic diagram of a generic computing system.

FIG. 6 is a schematic diagram of an example implementation to determine the power difference between the power measured following perturbation and the value computed using a predictive model based on a second order Lagrange polynomial.

FIG. 7 is a graph illustrating the performance of a tracking procedure.

Like reference symbols in the various drawings indicate like elements.

### DETAILED DESCRIPTION

Disclosed herein are techniques, systems, methods, devices, and other implementations, for estimating a maximum power point of a photovoltaic (PV) array. For example, in some embodiments, a solar power system includes a device that converts an electrical direct current produced in a PV array into an alternating current. The alternating current is then provided as an input into a computer-based system, which is configured, among other things, to track the MPP to enable efficiently harvesting power from the PV array. The computer-based system may further include a clock that is utilized to time intervals of the signal sampling period, intervals of the perturb cycle period, a perturb point, and an observe point. The alternating current is sampled at intervals, which are less than the interval of the perturb cycle, in order to generate a predictive model of power behavior of the array from which a trajectory of the predicted behavior of the PV array is generated. When the actual voltage of the array is perturbed, the difference between the actual power of the PV array and the predicted power at a subsequent time instant is determined. The MPP can be properly tracked in dynamic insolation conditions by allowing the direction of the next perturbation cycle to be correctly chosen based on the determined power difference. Other system implementations are possible.

In some embodiments, methods, systems, and other implementations are provided, including a method for power tracking that includes measuring a plurality of samples of power produced by a photovoltaic (PV) array over a first interval of time, determining, based on the measured plurality of samples of the power of the PV array, a non-linear predictive model of a behavior of the power produced by the PV array, and performing a first adjustment of the PV array's voltage at a second time instant subsequent to an end of the first interval of time. The method further includes measuring another sample of the power of the PV array with the adjusted voltage, and determining a power difference between the power of the PV array with the adjusted voltage at a third time instant and a computed power level of the PV array at the third time instant determined from the non-linear predictive model.

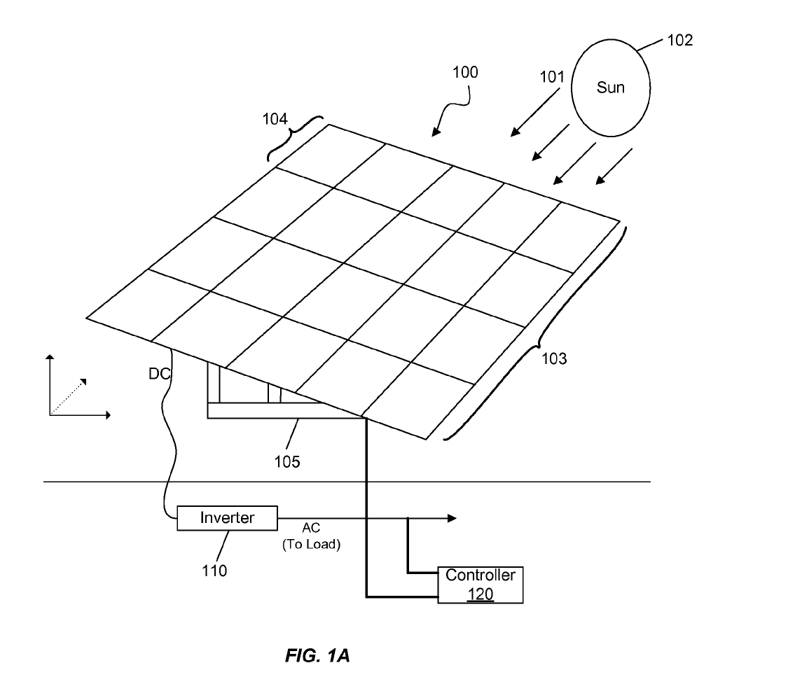

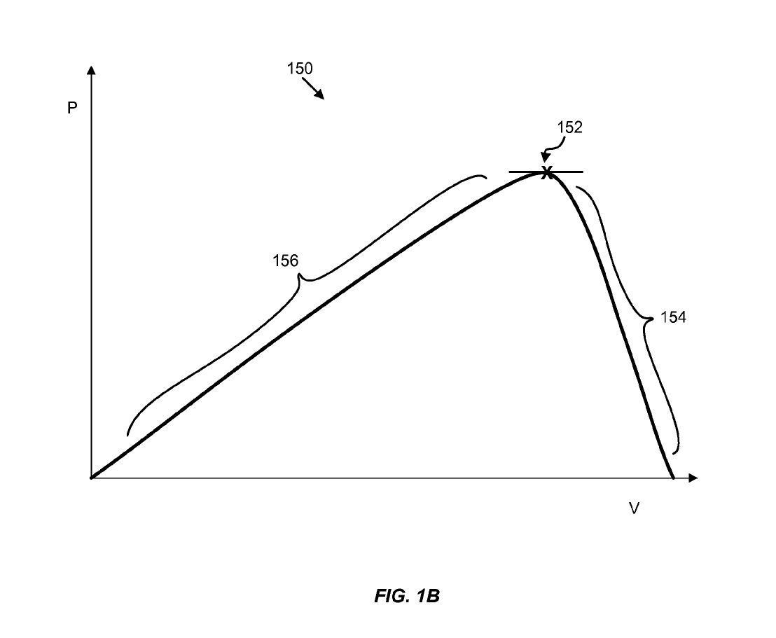

With reference to FIG. 1A, a schematic diagram of a solar panel system 100 to harvest solar energy is shown. The system 100 includes a plurality of photovoltaic (PV) modules (or cells), such as the PV module 104, arranged as a PV array 103. In some implementations, each PV module may comprise a connected series of photovoltaic cells. Surfaces of the PV cells, which, in some implementations, may be configured similarly to photodiodes, are irradiated with radiation 101 from the sun 102 to excite electrons and create a potential between two electrodes. In some embodiments, the energy produced by the cells creates a direct current (DC). To convert this DC electricity into usable power (e.g., in the form of alternating current), the array 103 is connected to an inverter 110 (also referred to as a converter) configured to convert DC to AC.

Solar power may be measured in insolation, which is the amount of power (kilowatt hours) collected over a known surface area (square meters) and over a given time period (day). The insolation changes with changes to environmental conditions, such as temperature, cloud cover and position of the sun, and thus, the power produced by the PV modules fluctuates (generally in a non-linear manner) when changes to the environment in which the PV array 103 is deployed occur. In some embodiments, the PV array 103 may be mounted on a moveable support 105, which can be adjusted to position the planar surface of the array at an angle with the sun that seeks to maximize the radiation received from the sun.

In order to extract energy from the solar panels according to the load demand, in some embodiments, techniques and procedures to identify optimal, or near optimal, operating points of the PV array are performed. For example, as load and environmental conditions affecting performance of the PV array change, the optimal voltage or current of the PV array varies. However, because PV arrays are generally configured to operate at a constant operating point (e.g., at a constant voltage), fluctuating load and/or environmental conditions may render operation of the PV array, configured to operate at a set voltage or current, as non-optimal. Accordingly, in some implementations, as load and environmental conditions change, the operating points of the PV array may be adjusted so as to identify the optimal (or near optimal) operating point for the PV array for the present load and/or environmental conditions.

In some embodiments, techniques/procedures such as a maximum power point tracking (MPPT) procedure may be utilized. The MPPT procedure is configured to determine, based on the supply and demand of the PV array and the load, an optimal voltage (when the PV array is configured to operate with a constant voltage and a variable current that varies with changing environmental and/or load conditions), and/or the optimal current (when the PV array is configured to operate with a constant current and a variable voltage level that varies with changing environmental and/or load conditions) to enable optimal, e.g., maximum or near maximum, power to be provided by the PV array. For example, and with reference to FIG. 1B showing an example graph 150 of power output behavior for a PV array as a function of the array's voltage, the point where the difference between the supply and demand is zero, or approximately zero (at a point 152 on the graph 150) corresponds to the maximum power point (MPP) of the PV array where the PV array is supplying power to the load substantially efficiently, and little or no additional power is being lost or required. The point on the graph at which maximum power is delivered corresponds to a point where the derivative of the graph, dP/dV, is equal to 0. At other points on the graph, the derivative dP/dV (as V increases) is not equal to 0, and the PV array is thus not operating at an optimal state. For example, a section 154 of the graph 150, corresponds to a derivative dP/dV being smaller than 0, and may be indicative that voltage levels are too high for given load conditions. In another example, points on the graph 150 where the derivative dP/dV is greater than 0 (dP/dV>0) as V increases, as depicted in the section 156 of the graph, may represent voltage levels that are too low for existing load conditions.

When a PV array is not operating at optimal or near optimal conditions, e.g., when the derivative dP/dV of the power vs. voltage curve is non-zero, a procedure, such as the Maximum Power Point Tracking (MPPT) method, may be implemented to iteratively adjust the voltage level of the PV array until optimal or near optimal power delivery by the PV array for the given load and/or environmental conditions is established.

For example, in some embodiments, an MPPT-based procedure may be implemented as a “perturb and observe” (P&O)-based procedure, in which the voltage of the PV array is periodically perturbed (e.g., the voltage produced by the PV array is adjusted), and the change in the current, and thus in the power, provided by the PV array as a result of the change in voltage, is observed. The difference between the observed power value and an earlier power value can thus provide a value representative of dP/dV. This procedure can be described according to the following equation:

P_{PV}(T)−P_{PV}(0)=x (1)

where, P_{PV} is the observed power of the photovoltaic array, T is the period of the perturb interval (in this example), and x is the difference in power over one period (T). If the change in the current (or power) is zero, i.e., x=0, the MPP is being realized. However, if the change in the power is such that the power increased or decreased, the MPP has shifted in accordance with the observed change. For example, if dP/dV>0, it can be concluded that the perturbation caused the array's operating power to move towards MPP, whereas if dP/dV<0, it can be concluded that the perturbation caused the array's operating power to move away from the MPP.

Accordingly, to implement MPPT procedures, the system 100 depicted in FIG. 1A may include a controller 120 (e.g., a processor-based controller, a DSP processor, an application-specific integrated circuit, and/or any combination thereof) configured to determine whether non-optimal conditions of the systems and devices exist (e.g., by tracking the behavior of the power produced as a function of changing voltage and/or current), and to controllably adjust the voltage/current to converge to an optimal or near optimal power behavior for the PV array. For example, in situations where a controller coupled to a PV array indicates non-optimal power conditions, e.g., by determining that dP/dV is non-zero, the controller is configured to cause an adjustment of the voltage of PV array, and to repeat these operations if the voltage adjustment did not result in establishment of optimal or near-optimal conditions (e.g., MPP was not established). As shown in FIG. 1A, the controller 120 may be electrically coupled to, for example, the output of the inverter 110 (e.g., to enable determining power values) and/or to the PV array 103 (e.g., to control the array's voltage and/or current).

MPPT Procedures implemented in accordance with, for example, Equation 1 above, measure the power (e.g., multiplying the array's voltage by the array's current) at one time instant (e.g., when the system was perturbed by, for example, causing the voltage of the array to increase or decrease), and at a subsequent time instant, T (the time period between the time instants should be sufficiently long to enable the power behavior of the array to settle down).

The computed power difference according to Equation 1 does not indicate what contributed to the power measured at the subsequent time instant. Particularly, if during the period of measurement environmental and load conditions were unchanged, then it can be assumed that the power measured at time instant T resulted substantially from the adjustment made to the voltage of the PV array. However, if there were changes to the environmental conditions in which the PV array is operating (temperature, cloud coverage, sun brightness, etc.) then these environmental changes may have contributed, at least to some extent, to the measured change in the power supplied by the PV array (for the purpose of explanation, it will be assumed that load conditions are not changed during the PV array power measurement period). It is therefore difficult to determine if the “power delta” sign, based on which the direction of tracking is determined, was in response to either the voltage perturbation, insolation changes, or both. Accordingly, under these circumstances, a computation of power difference in accordance with Equation 1 may provide a value that would not be an accurate indication of whether further adjustments to the voltage of the PV array are necessary, and/or in what direction (e.g., voltage increase, voltage decrease) the adjustment should be made. Consequently, power optimization procedures, such as the MPPT procedure, may be tracking in the wrong direction.

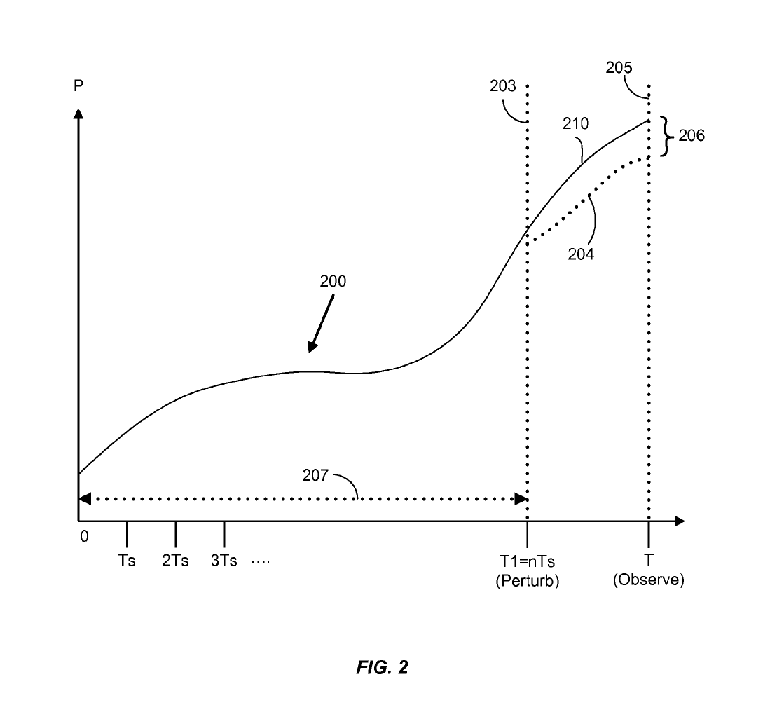

Therefore, in some embodiments, power optimization procedures for PV arrays that take into account the effect/contribution of insolation changes may be implemented. Particularly, in some implementations, computation of the power difference may be performed in accordance with a model that incorporates the effect/contribution of insolation changes to changes in the power supplied/produced by a PV array. With reference to FIG. 2, a graph 200 of the power behavior of a PV array over a period of time as a result of insolation changes and voltage perturbation is shown. As illustrated in FIG. 2, during the period 0<t<T1 (i.e., the period preceding the instant of perturbation), the power is shown to vary due to, in the example of the graph 200, insolation changes (e.g., changes in the temperature, cloud coverage, etc.). During that period, also referred to as the “identification period” or “sampling period,” the power behavior of the PV array resulting from insolation changes may be sampled, and based on the sample points recorded, a model representative of power behavior as a result of insolation changes is determined. The derived model can therefore be used to predict the power behavior of the PV array, as a result of insolation changes, at a time subsequent to the end of the sampling period. FIG. 2 shows a dashed projection 204 corresponding to the power behavior of the PV array predicted from the model derived from the samples collected during the period 0<t<T1. The dashed projection 204 is a predicted extension of sampled portion of the graph 200 prior to its perturbation, and therefore does not represent the behavior of the power level of the PV array resulting from perturbation of the PV array.

As further shown in FIG. 2, at a time subsequent to the sampling period, the PV array system is perturbed (e.g., its voltage level is altered), resulting in power behavior represented, in the example of FIG. 2, by the solid line portion 210 of the graph 200. The solid line portion 210 represents the behavior of the power of the PV array resulting from the effect of both the perturbation and the insolation changes. Generally, the model derived from the samples can provide reasonable short term predictions of the power behavior from insolation changes (or any other factor which is to be modeled), but the accuracy and validity of the predicted behavior diminishes over time. As can be seen from FIG. 2, the effect the perturbation has on the power behavior of the PV array can be determined by identifying, using the derived model (represented by the dashed portion 204 depicted in FIG. 2), the effect insolation changes are predicted to have on the power behavior, and subtracting from the overall power behavior (represented by the solid line section 210 of the graph 200) the predicted effect/contribution of the insolation changes on the power behavior. Accordingly, in some embodiments, the effect of perturbation can be represented as:

P_{PV}(T)−P_{PV}_{_{—}}_{Model}(T) (2)

where T is a time instant, subsequent to the end of the sampling period and to the time instant when the PV array was perturbed, when the power supplied by the PV array is sampled. The difference between the actual power supplied by PV array (such actual power being affected by, for example, the perturbation and insolation changes) and the power level predicted using the mathematical model modeling the power behavior of the PV array as a result of insolation changes, provides a value representative of effect of perturbation on the power supplied by the PV array. The resultant value will therefore provide a more accurate indication of dP/dV, and will thus provide a more accurate and reliable tracking of the power behavior of the PV array so as to more quickly achieve an optimal, or near optimal, voltage level (or current level, in situations where the PV array has a near constant current and fluctuating voltage).

As will be described in greater details below, in some implementations, the model derived to predict the power behavior of the PV array as a result of insolation changes (at least for short term prediction) may be a non-linear model, e.g., high order models such as, for example, second and/or third order models. Use of non-linear models provide a more accurate and robust representation (e.g., as compared to representations provided, for example, by linear models) of a rate of change (in this case, the PV array's power rate of change), and therefore may enable more accurate tracking of the PV array's MPP. Additionally, use of a non-linear model enables non-constant sampling (i.e., using varying sampling intervals in which the sampling intervals between successive samples are not necessarily the same) to obtain the samples that are used to derive the non-linear representation corresponding to the samples. In some embodiments, and as will be described below in greater detail, derivation of non-linear predictive models to represent the behavior of PV array power resulting from insolation changes (or resulting from other factors) may be based on one or more of, for example, interpolation polynomials, a least square technique, and/or trigonometric interpolation.

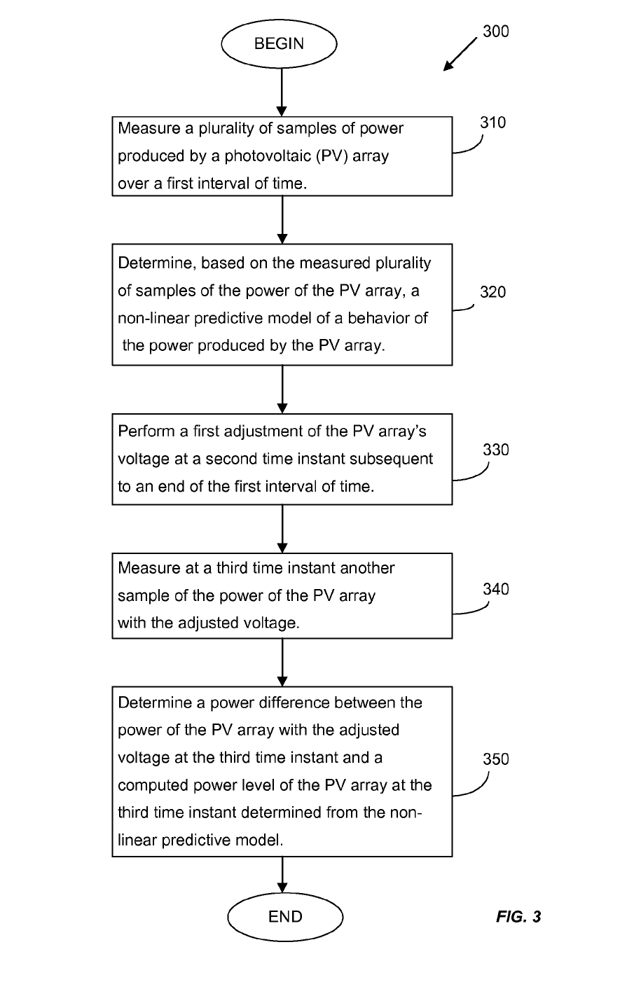

With reference to FIG. 3, a flow chart of a power tracking procedure 300 that takes into account the effect of insolation changes on the power tracking functionality performed by, for example, the system 100, is shown. Implementation of the procedure 300 may be based, for example, on configuring the controller 120 depicted in FIG. 1 to perform the operations described herein. As noted, to determine the effect insolation changes (or other factors) have on the power behavior of a PV array, such as the PV array 103 depicted in FIG. 1, a plurality of samples of power produced by the PV array over a first interval of time is measured 310. Sample measurements can be performed, for example, by separately measuring the voltage and current produced by the PV array (e.g., using voltmeter, ammeters, etc.) and multiplying the two to obtain an instant power value supplied by the PV array. In some embodiments, the measured electrical attributes may be performed with respect to the output of the inverter (e.g., the inverter 110) of the PV array. Measuring power samples may also be performed, for example, by dividing the identification period (also called the “sampling period) into a number of intervals. In some embodiments, and as shown in FIG. 2, the identification period may be divided to substantially equal length intervals of duration Tₛ. As noted, when non-linear models are derived to represent the behavior of power supplied by the PV array, the sampling period does not have to be constant, and the intervals between successive samples may vary over the duration of the identification period. In some implementations, the measured samples may be obtained by using a sample-and-hold circuit to determine the voltage level and/or current level at the measurement instants, and using, for example, an analog-to-digital converter (ADC) to digitize the measured samples. Such sample-and-hold circuit(s) and/or an ADC may be part of the example controller 120 of FIG. 1.

Based on the measured plurality of samples of the power level of the PV array, a non-linear predictive model of a behavior of the power produced by the PV array may be determined 320. As noted, in some embodiments, a non-linear model based on interpolation polynomials may be derived. Various forms may be used to represent interpolating polynomials. For example, an interpolating polynomial function may be represented as a linear combination of orthogonal polynomials. In some implementations, an interpolating polynomial may be represented as combination of Lagrangian polynomials. Particularly, a combination of Lagrangian polynomials may be represented as:

L(x) [symbol] ⁿ/j=0Σyⱼlⱼ(t) (3)

In order to determine the number of samples from a given set of, for example, n+1 data points at the intervals nTₛ at which the signal is sampled, the data points can be represented as xⱼ=jTₛ and yⱼ=Pₚᵥ(jTₛ), where j=0 . . . n. It is to be noted that although in this particular example the sampling interval is substantially constant, a non-constant (irregular) sampling interval may be used instead. Utilizing the aforementioned representation in equation (3), the polynomials can be expanded as the following mathematical function:

lⱼ(t)=(0≦i≦n,i≠j)Π(t−xᵢ)/(xⱼ−xᵢ)=(t−x₀)/(xⱼ−x₀) . . . (t−xⱼ₋₁)/(xⱼ−xⱼ₋₁)·(t−xⱼ₊₁)/(xⱼ−xⱼ₊₁) (4)

When the system is running on a clocked time interval, it is assumed that the time interval at which the signal is sampled is a unity time interval, e.g., Tₛ=1, 2, 3, etc. Equation (4) can then be reduced to:

lⱼ(t)=(0≦i≦n,i≠j)Π(t−i)/(j−i)=(t−0)/(j−0) . . . (t−(j−1)/(j−1)·(t−(j+1)/(j−(j+1) (5)

Equation (5) can thus be utilized to compute the sampled signal power at any number of intervals “n” to collect data points which predict the trajectory of the PV power signal. The integration of the Equation (5) provides the predictive PV power signal function Pₚᵥ_{_{—}}_{model}(t) having n+1 samples over a period Tₛ represented as:

Pₚᵥ_{_{—}}_{model}((n+1)Tₛ)|₍ₙ₋ᵢ₎=L(n+1)=y₀l₀(n+1)+y₁l₁(n+1) . . . y₍ₙ₎(n+1)l₍ₙ₎(n+1) (6)

In Equation (6), each l₍ₙ₎ can be derived from equation (5), with each selection of “n” producing “n+1” data points.

As an example, consider a situation where n=2. In this case, there are 3 sampling points, giving rise to the following expressions:

l₀(t)=(t−1)/(0−1)·(t−2)/(0−2)=(t−1)(t−2)/2

l(t)=(t−0)/(1−0)·(t−2)/(1−2)=−t(t−2)

l₂(t)=(t−0)/(2−0)·(t−1)/(2−1)=t(t−1)/2

P_{PV}_{_{—}}_{model}(t)=y₀l₀(t)+y₁l₁(t)+y₂l₂(t)

With the above expression for P_{PV}_{_{—}}_{model}(t) the value of the function for t=(n+1)Tₛ may be computed as follows:

$${P}_{PV \_ model} ( ( n + 1 ) {T}_{s} ) = L ( n + 1 ) {\vert}_{n = 2} = L ( 3 )$$

$$\begin{matrix}L ( 3 ) = {y}_{0} {𝓁}_{0} ( 3 ) + {y}_{1} {𝓁}_{1} ( 3 ) + {y}_{2} {𝓁}_{2} ( 3 ) \\ = {y}_{0} ( 3 \text{-} 1 ) ( 3 \text{-} 2 ) \text{/} 2 - 3 {y}_{1} ( 3 \text{-} 2 ) + {y}_{2} ( 3 \text{-} 0 ) ( 3 \text{-} 1 ) \text{/} 2 \\ = {y}_{0} - 3 {y}_{1} + 3 {y}_{2}\end{matrix}$$

Therefore, P_{PV}_{_{—}}_{model}(3Tₛ)=P_{PV}(0)−3P_{PV}(Tₛ)+3P_{PV}(2Tₛ)

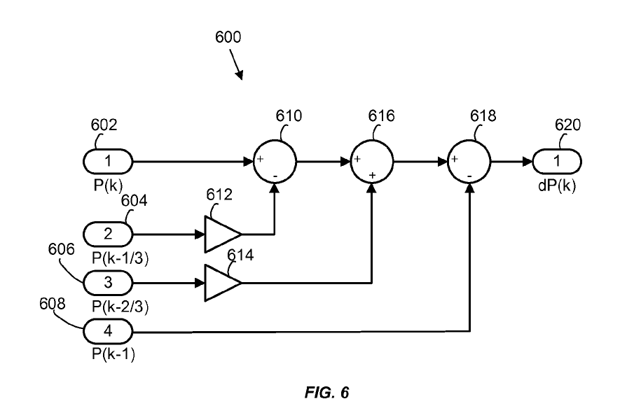

FIG. 6 is a schematic diagram of an example DSP implementation 600 to determine the power difference between the power (or a discretized value thereof) measured following perturbation (i.e., P(k)) and the value computed using a second order Lagrange polynomial used to predict the power behavior of a PV array resulting, for example, from insolation changes. The power differential can be expressed as:

P(k)−P_{PV}_{_{—}}_{model}(k),

Substituting the expression for the 2^{nd} order Lagrangian P_{PV}_{_{—}}_{model} derived above provides:

P(k)−[P(k−1)−3P(k−⅔)+3P(k−⅓)], where the samples are a discretized distance of ⅓ from each other.

Accordingly:

dP(k)=P(k)−P(k−1)+3P(k−⅔)−3P(k−⅓)

Thus, to obtain output value 620, corresponding to dP(k), the implementation 600 includes a summing operator 610 that adds the sample 602, corresponding to P(k), to the negative of the preceding sample 604 (corresponding to P(k−⅓) that was amplified by an amplifier 612 with a gain of 3. The resultant sum of the summing operation at 610 is added, using the summing operator 616, to a resultant amplified valued of the sample 606, corresponding to P(k−⅔). The sample 606 is amplified using an amplifier 614 that also has a gain of 3. Finally, the result of the summing operator 616 is added to the negative of the sample 608, corresponding to P(k−1). It is to be noted that the implementation of FIG. 6 is just one example of a realization a predictive model and for determining the power difference according to, in this example, dP(k)=P(k)−P(k−1)+3P(k−⅔)−3P(k−⅓), and that other implementations may be used instead of, or in addition to, the DSP-based realization depicted in FIG. 6.

As another example, consider the situation where n=3. In this case, there are 4 sampling points, giving rise to the following expressions:

l₀(t)=(t−1)/(0−1)−(t−2)/(0−2)·(t−3)/(0−3)=(t−1)(t−2)(t−3)/(−6)

l₁(t)=(t−0)/(1−0)−(t−2)/(1−2)·(t−3)/(1−3)=t(t−2)(t−3)/2

l₂(t)=(t−0)/(2−0)−(t−1)/(2−1)·(t−3)/(2−3)=t(t−1)(t−3)/(−2)

l₃(t)=(t−0)/(3−0)−(t−1)/(3−1)·(t−2)/(3−2)=t(t−1)(t−2)/6

With above expressions, P_{PV}_{_{—}}_{model}(t) for t=(n+1)Tₛ may be computed as follows:

$${P}_{PV \_ model} ( ( n + 1 ) {T}_{s} ) {\vert}_{n = 3} = L ( 4 )$$

$$\begin{matrix}L ( 4 ) = {y}_{0} ( 4 \text{-} 1 ) ( 4 \text{-} 2 ) ( 4 \text{-} 3 ) \text{/} ( - 6 ) + {y}_{1} 4 ( 4 \text{-} 2 ) ( 4 \text{-} 3 ) / 2 + {y}_{2} 4 ( 4 \text{-} 1 ) ( 4 \text{-} 3 ) \text{/} 2 \\ = {y}_{3} 4 ( 4 \text{-} 1 ) ( 4 \text{-} 2 ) \text{/} 6 \\ = - {y}_{0} + 4 {y}_{1} - 6 {y}_{2} + 4 {y}_{3}\end{matrix}$$

Therefore, the predicted power level at 4Ts, as computed based on the above derived expression, is:

P_{PV}_{_{—}}_{model}(4Tₛ)=−P_{PV}(0)+4P_{PV}(Tₛ)−6P_{PV}(2Tₛ)+4P_{PV}(3Tₛ)

In some embodiments, derivation of another type of non-linear predictive model to represent the power behavior due to, for example, insolation changes, may be based on the Least Square Method. Using this technique, the resulting signal model is generally a polynomial function with a function order of in where m<n+1. The parameter in may be selected based on the desired modeling accuracy. The implementation of the least square method to facilitate derivation of a model based on the samples collected can be, in some embodiments, in the form of recursive calculations.

Derivation of a predictive model based on a least squares procedure may be implemented as follows. Given a set of n+1 data points, i.e., (x₀,y₀), . . . , (xₙ,yₙ), where xⱼ=jTₛ and yⱼ=P_{PV}(jTₛ), and where j=0 n, the objective is to determine coefficients of the following polynomial:

P_{PV}_{_{—}}_{model}(t)=y(t)=a₀+a₁t+a₂t²+ . . . +aₘt^{m},

such that the criterion function φ is minimized, where, for example, φ may be:

φ=Σᵢ₌₀ⁿ[yi−(a₀+a₁xᵢ+a₂xᵢ²+ . . . +aₘxᵢ^{m})]²

The coefficients a₀ . . . aₘ are obtained as a solution of the following system of linear equations:

$$\begin{matrix}\begin{matrix}\begin{matrix}{na}_{0} + {a}_{1} {\sum }_{i = 0}^{n} {x}_{i} + {a}_{2} {\sum }_{i = 0}^{n} {x}_{i}^{2} + … + {a}_{m} {\sum }_{i = 0}^{n} {x}_{i}^{m} = {\sum }_{i = 0}^{n} {y}_{i} \\ {a}_{0} {\sum }_{i = 0}^{n} {x}_{i} + {a}_{1} {\sum }_{i = 0}^{n} {x}_{i}^{2} + {a}_{2} {\sum }_{i = 0}^{n} {x}_{i}^{3} + … + {a}_{m} {\sum }_{i = 0}^{n} {x}_{i}^{m + 1} = {\sum }_{i = 0}^{n} {x}_{i} {y}_{i}\end{matrix} \\ …\end{matrix} \\ {a}_{0} {\sum }_{i = 0}^{n} {x}_{i}^{m} + {a}_{1} {\sum }_{i = 0}^{n} {x}_{i}^{m + 1} + {a}_{2} {\sum }_{i = 0}^{n} {x}_{i}^{m + 2} + … + {a}_{m} {\sum }_{i = 0}^{n} {x}_{i}^{2 m} = {\sum }_{i = 0}^{n} {x}_{i}^{m} {y}_{i}\end{matrix}$$

As an example, consider the situation where n=2, in which case there are 3 data sets, namely, (x₀,y₀), (x₁,y₁), and (x₂,y₂). Let Tₛ=1, in which case x₀=0, x₁=1, and x₂=2. In this example, m=1, which means that in this case, when a statistical procedure, such as the least square procedure, is used to derive the predictive model, the predictive model may be represented as a first order (linear) function. Thus, PVₚᵥ_{_{—}}_{model} can be represented as:

PVₚᵥ_{_{—}}_{model}=a₀+a₁t

where a₀ and a₁ are obtained from:

3a₀+a₁(x₀+x₁+x₂)=y₀+y₁+y₂.

a₀(x0+x1+x2)+a₁(x₀²+x₁²+x₂²)=x₀y₀+x₁y₁+x₂y₂

When substituting the values of x₀=0, x₁=1, and x₂=2, the following set of equations are obtained:

3a₀+3a₁=y₀+y₁+y₂; and

3a₀+5a₁=y₁+2y₂

and a₀ and a₁ can be determined to be:

a₁=(y₂−y₀)/2, and a₀=⅚y₀+⅓y₁−⅙y₂

PVₚᵥ_{_{—}}_{model} may therefore be expressed as:

PVₚᵥ_{_{—}}_{model}=(y₂−y₀)t/2+⅚y₀+⅓y₁−⅙y₂

Thus, at the time t=(n+1)Tₛ|_{n=2,Ts=1}=3, PVₚᵥ_{_{—}}_{model} is determined to be:

$$\begin{matrix}{P}_{PV \_ model} ( ( n + 1 ) {T}_{s} {\vert}_{n = 2 , Ts = 1} ) = {P}_{PV \_ model} ( 3 ) \\ = 3 \text{/} 2 ( {y}_{2} - {y}_{0} ) + 5 \text{/} 6 {y}_{0} + 1 \text{/} 3 {y}_{1} - 1 \text{/} 6 {y}_{2} \\ = - 2 \text{/} 3 {y}_{0} + 1 \text{/} 3 {y}_{1} + 4 \text{/} 3 {y}_{2}\end{matrix}$$

In yet another example, in some embodiments, derivation of another type of non-linear predictive model to represent the power behavior due to, for example, insolation changes, may be based on trigonometric interpolation. This derivation technique is suitable, for example, in situations where the model is to be represented as a periodic function. Consider, for example, the use of trigonometric interpolation for n+1 data points, namely (x₀,y₀), . . . , (xₙ,yₙ). A function F(x) may be represented as follows:

$$F ( x ) = \begin{matrix}{y}_{0} \begin{matrix}[ sin 1 \text{/} 2 ( x - {x}_{1} ) sin 1 \text{/} 2 ( x - {x}_{2} ) … sin 1 \text{/} 2 ( x - {x}_{n} ) ] / \\ [ sin 1 \text{/} 2 ( {x}_{0} - {x}_{1} ) sin 1 \text{/} 2 ( {x}_{0} - {x}_{2} ) … sin 1 \text{/} 2 ( {x}_{0} - {x}_{n} ) ]\end{matrix} + \\ {y}_{1} \begin{matrix}[ sin 1 \text{/} 2 ( x - {x}_{0} ) sin 1 \text{/} 2 ( x - {x}_{2} ) … sin 1 \text{/} 2 ( x - {x}_{n} ) ] / \\ [ sin 1 \text{/} 2 ( {x}_{1} - {x}_{0} ) sin 1 \text{/} 2 ( {x}_{1} - {x}_{2} ) … sin 1 \text{/} 2 ( {x}_{1} - {x}_{n} ) ]\end{matrix} + … + \\ {y}_{n} \begin{matrix}[ sin 1 \text{/} 2 ( x - {x}_{0} ) sin 1 \text{/} 2 ( x - {x}_{2} ) … sin 1 \text{/} 2 ( x - {x}_{n - 1} ) ] / \\ [ sin 1 \text{/} 2 ( {x}_{n} - {x}_{0} ) sin 1 \text{/} 2 ( {x}_{n} - {x}_{2} ) … sin 1 \text{/} 2 ( {x}_{n} - {x}_{n - 1} ) ]\end{matrix}\end{matrix}$$

As an example, consider the situation where n=3. In this case, there are 4 sampling points which, for the purpose of illustration, are sampled at xⱼ=jTₛ, where j=0, 1, 2, 3. With four (4) sample points, the predictive model, P_{PV}_{_{—}}_{model}(t) may be expressed as follows:

P_{PV}_{_{—}}_{model}(t)=F(t)=y₀[sin ½(t−1)sin ½(t−2)sin ½(t−3)]/[sin ½(0−1)sin ½(0−2)sin ½(0−3)]+y₁[sin ½(t−0)sin ½(t−2)sin ½(t−3)]/[sin ½(1−0)sin ½(1−2)sin ½(1−3)]+y₂[sin ½(t−0)sin ½(t−1)sin ½(t−3)]/[sin ½(2−0)sin ½(2−1)sin ½(2−3)]+y₃[sin ½(t−0)sin ½(t−1)sin ½(t−2)]/[sin ½(3−0)sin ½(3−1)sin ½(3−2)]

For ease of illustration, in the above model derivation examples, the sampling points were assumed to be taken at equal duration intervals. However, as noted, derivations to obtain predictive model representations for the power behavior may be performed with sample points taken at non-constant (e.g., irregular) intervals. Additionally, although three different derivation techniques were illustrated, other techniques/procedures to determine non-linear predictive model to represent the power behavior of the PV array may be used in addition to or instead of the any of the above illustrated techniques/procedures.

Turning back to FIG. 3, after measuring/obtaining the samples, and determining, based on the samples obtained, a non-linear model to represent the power behavior of the PV array, tracking operations to determine the maximum power point using the derived non-linear model may be performed. Thus, a first adjustment is performed 330 of the PV array's voltage at a second time instant subsequent to an end of the first interval of time (during which the power samples were measured/obtained). For example, the voltage adjustment performed, i.e., perturbation of the system, may be to increase or decrease the voltage of the PV array by some pre-determined amount, or by an amount that depends on the present voltage level (as may have been measured, for example, when the last sample was obtained). In some embodiments, the determination of whether to initially increase or decrease the voltage (i.e., before any power difference computation is performed) may be based on some pre-determined set of rules (e.g., that the voltage is to initially be increased, that a decision as to initially increase or decrease the voltage may be based on the present voltage level or on the difference between power levels of the last two samples obtained, etc.) In the example of FIG. 2, voltage adjustment, or perturbation, occurs at the time instant T1=nTs (the time instant T1 is also referred to as the “point of perturbation”). As noted, in some embodiments, the PV array may be configured to output a substantially constant current, and to have varying voltage that depends, for example, on load changes, insolation changes, etc. Under those circumstances, perturbation of the system may be performed by making a current adjustment to the PV array, and tracking the maximum power point resulting from such current perturbations.

At a third time instant T, where T>T1, another sample of the power of the PV array with an adjusted electrical attribute (e.g., adjusted voltage, in the example of FIG. 2) is measured 340 (i.e., the observation of the system following the perturbation of the system). The measurement of the power level of the PV array with the adjusted electrical attribute may be performed using a sample-and-hold circuit to determine the voltage level and/or current level at the instant of measurements, and by using, for example, an analog-to-digital converter to digitize the measured sample. Generally, the time duration between “T1” and “T” should be sufficiently long to enable the system to respond to the adjustment performed.

Having obtained the other sample, a power difference is determined 350 between the power of the PV array with the adjusted voltage at the third time instant and a computed power level of the PV array at the third time instant determined from using the non-linear predictive model. Thus, in some implementations, a determination is made of P_{PV}(T)−P_{PV}_{_{—}}_{model}(T). The power difference therefore provides a value indicative of the effect the perturbation had on the power being tracked by attempting to remove the contribution that insolation changes (computed using the determined non-linear model), or any other factor represented by this or some other non-linear predictive model, had on the power being tracked.

The determined power difference may be utilized to track the MPP of the PV array and control the output of the PV array in relation to the load. For example, the determined power difference can be utilized to determine the next direction of perturbation (e.g., adjustment of an attribute of the PV array, be it the voltage or current) based on the sign of a result of the power difference, and to use the resultant sign (positive “+”, or negative “−”) to control the direction of the perturbation during the next cycle. Thus, in some embodiments, the procedures implemented to track the maximum power point of a PV array may include performing another adjustment of the voltage of the PV array based on the determined power difference between the power of the PV array with the adjusted voltage at the third time instant and the computed power level of the PV array at the third time instant as determined from the non-linear predictive model.

For example, in response to a determination that the power difference is greater than ε, where ε is a pre-determined value that is generally smaller than the power level of the PV array with the adjusted voltage (ε may be equal to 0 in some embodiments), if the preceding adjustment of the voltage (or another electrical attribute) of the PV array was a voltage increase then the next voltage adjustment for the PV array would be to increase the voltage. Particularly, if the computed power difference is determined to be greater than ε (e.g., greater than 0), this may indicate that the power is being tracked in the right direction. Therefore, if the previous adjustment was to increase the voltage, then the next adjustment should also be a voltage increase (e.g., by some pre-determined amount, by an amount that is based on, for example, the present voltage or power level, etc.) If the previous adjustment was a voltage decrease, then the next adjustment should also be a voltage decrease.

Conversely, if it is determined that the power difference is less than ε, and the preceding adjustment of the PV array was a voltage increase, then the next adjustment of the PV array's electrical attribute(s) may be to decrease the voltage. Particularly, because a computed power difference that is less than ε (e.g., less than 0) may indicate that the maximum power point is being tracked in the wrong direction (i.e., moving away from the maximum power point), if the previous adjustment was to increase the voltage of the PV array, then the voltage may have to be decreased on the next adjustment so as to reverse to tracking direction. Similarly, if it is determined that the power difference is less than ε, and the previous adjustment was a voltage decrease, then the next adjustment may be a voltage increase.

In some embodiments, the process of adjusting the electrical attribute(s) of the PV array may be repeated until, for example, an absolute value of the determined power difference is less than some pre-determined value, indicating that the PV array may have substantially or approximately reached its maximum power point.

While the implementations discussed above refer to the perturb and observe technique, similar implementations may also be realized in relation to other types of tracking techniques, including, for example, the incremental conductance procedure, the constant voltage procedure, etc. For example, in implementations based on incremental conductance procedure, the incremental conductance dI/dV is determined so as to compute the sign of dP/dV. With this procedure, the system is determined to have reached its MPP when dI/dV=−i/v. If the system has not reached its MPP yet, the system continues to be perturbed.

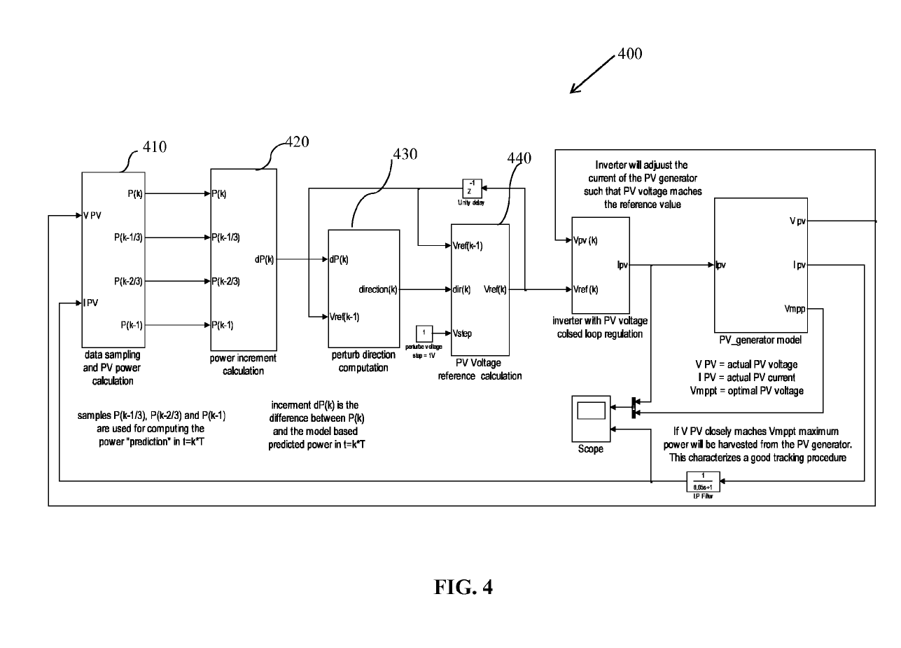

With reference to FIG. 4, a schematic diagram of an example system implementation 400 to perform a tracking procedure, such as that performed by the procedure 300 of FIG. 3, is shown. In some embodiments, the system 400 may be implemented, at least in part, as the controller 120 of FIG. 1A. The system 400 may include, for example, a sampling and PV power calculation module 410 (also referred to as a signal identification unit/module) to measure one or more samples of a power level produced by a PV array (such as the PV array 103), and may include sample-and-hold circuits and analog-to-digital converters. The Data Sampling and PV Power Calculation module 410 samples the voltage and current of the PV generator, computes power and provides the input data samples to the Power Increment Calculation module 420. The input to the Power Increment Calculation module 420 may be implemented, in some embodiments, to receive three (3) samples of the power signal taken before a perturbation (e.g., P(k−⅓), P(k−⅔) and P(k−1)), and one sample of the power signal taken after the perturbation P(k). Other implementations (e.g., using different sample sequences) may be used. The Power Increment Calculation module 420 of the example system 400 uses the “before perturbation samples,” e.g., P(k−⅓), P(k−⅔) and P(k−1), to construct, for example, a non-linear predictive model, and to determine a predicted (expected) power after the perturbation model, i.e., P_{model}(kT). As described herein, the predictive model may be derived based on interpolation polynomials (e.g., to derive a Lagrangian polynomial based model), a least square technique, a trigonometric interpolation technique, etc. Having computed a predicted power level using the derived model, a power difference may be computed, e.g., based on dP(kT)=P(kT)−P_{model}(kT).

The example system 400 also includes a Perturb Direction Computation module 430 which maintains a perturbation history (e.g., previous perturbation direction). The module determines, based on the power difference dP(kT) and the previous perturbation direction, what the next perturbation direction should be. For example if the previous PV voltage perturbation was in a positive direction (direction(k−1)>0) and the power difference (also referred to as “power increment”) is positive (i.e., dP(k)>0) then the next perturbation will be in a positive direction too. However if the power difference is negative (i.e., dP(k)<0) than the perturbation direction at t=kT should have the opposite sign to the direction in t=(k−1)T.

As further shown in FIG. 4, the example system 400 also includes a PV Voltage Reference Calculation module 440 configured to receive the direction command (e.g., from a module/unit such as the Perturb Direction Computation module 430 of the system 400) and to compute a PV voltage reference as follows:

If direction(k)>0 than: Vref(k)=Vref(k−1)+V_{perturbe step}

If direction(k)<0 than: Vref(k)=Vref(k−1)−V_{perturbe step}

where V_{perturbe step} represents a perturbation step voltage, which may be a pre-determined step voltage, or may be an adjustable dynamically derived value. In some embodiments, Vref(k) may also be compared to an associated minimum and maximum limits and clipped to those limiting values. The minimum and maximum limits may be based on the PV generator, Inverter, and/or power converter specifications. The computed Vref(k) is provided to an inverter module configured, among other things, to adjust the current of the PV generator such that the PV voltage converges to the reference voltage level.

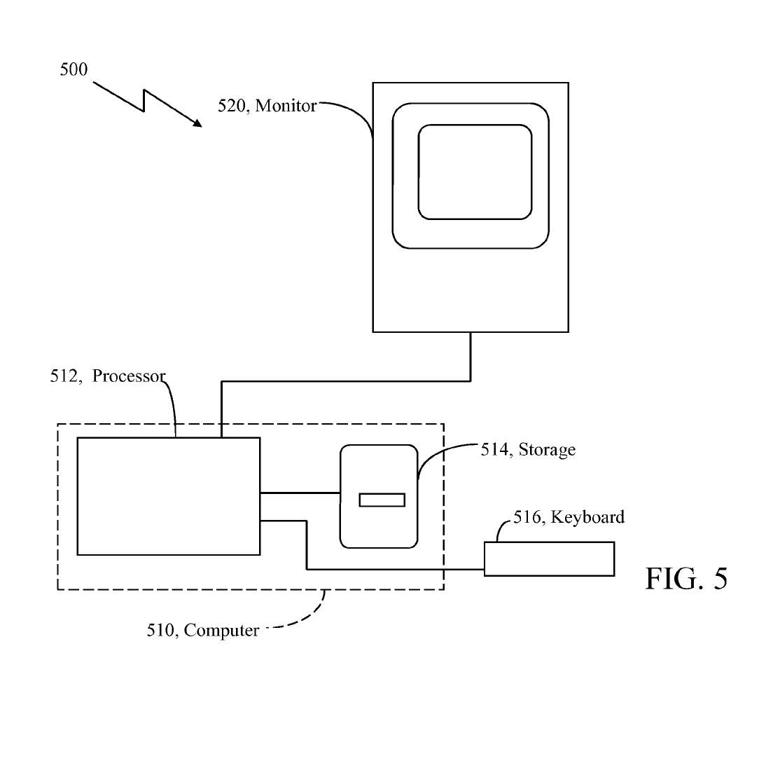

Performing the tracking and control procedures described herein may be facilitated, in some implementations, by a processor-based computing system which, for example, may be used to implement, at least partly, the controller 120 of FIG. 1. With reference to FIG. 5, a schematic diagram of a generic computing system 500 is shown. The computing system 500 includes a processor-based device 510 such as a personal computer, a specialized computing device, and so forth, that typically includes a central processor unit 512. In addition to the CPU 512, the system may include a main memory, cache memory and bus interface circuits (not shown). The processor-based device 510 may include a mass storage element 514, such as a hard drive and/or a flash drive associated with the computer system. The computing system 500 may further include a keyboard, or keypad, 516, and a monitor 520, e.g., a CRT (cathode ray tube) or LCD (liquid crystal display) monitor, that may be placed where a user can access them.

The processor-based device 510 is configured to facilitate, for example, the implementation of the tracking procedure, including facilitating measurement of sample points of the power output generated using a PV array, determining a non-linear predictive model representative of the power behavior of the PV array system resulting from such factors as insolation changes, determining whether power tracking is proceeding in the right direction, etc. The storage device 514 may thus include a computer program product that when executed on the processor-based device 510 causes the processor-based device to perform operations to facilitate the implementation of the above-described procedures. The processor-based device may further include peripheral devices to enable input/output functionality. Such peripheral devices may include, for example, a CD-ROM drive and/or flash drive, a network connection (implemented using, for example, a USB port, a wireless transceiver, etc.), for downloading related content to the connected system. Such peripheral devices may also be used for downloading software containing computer instructions to enable general operation of the respective system/device. Alternatively and/or additionally, in some embodiments, special purpose logic circuitry, e.g., an FPGA (field programmable gate array), a DSP processor, or an ASIC (application-specific integrated circuit) may be used in the implementation of the system 500. For example, in some implementations, a DSP processor may be used to implement the non-linear predictive model used to compute the predicted power behavior of the PV array due to, for example, insolation changes (or some other factor). An example of such an implementation is illustrated in FIG. 6 (as was more particularly described above). Other modules that may be included with the processor-based device 510 are speakers, a sound card, a pointing device, e.g., a mouse or a trackball, by which the user can provide input to the computing system 500. The processor-based device 510 may include an operating system.

Computer programs (also known as programs, software, software applications or code) include machine instructions for a programmable processor, and may be implemented in a high-level procedural and/or object-oriented programming language, and/or in assembly/machine language. As used herein, the term “machine-readable medium” refers to any non-transitory computer program product, apparatus and/or device (e.g., magnetic discs, optical disks, memory, Programmable Logic Devices (PLDs)) used to provide machine instructions and/or data to a programmable processor, including a non-transitory machine-readable medium that receives machine instructions as a machine-readable signal.

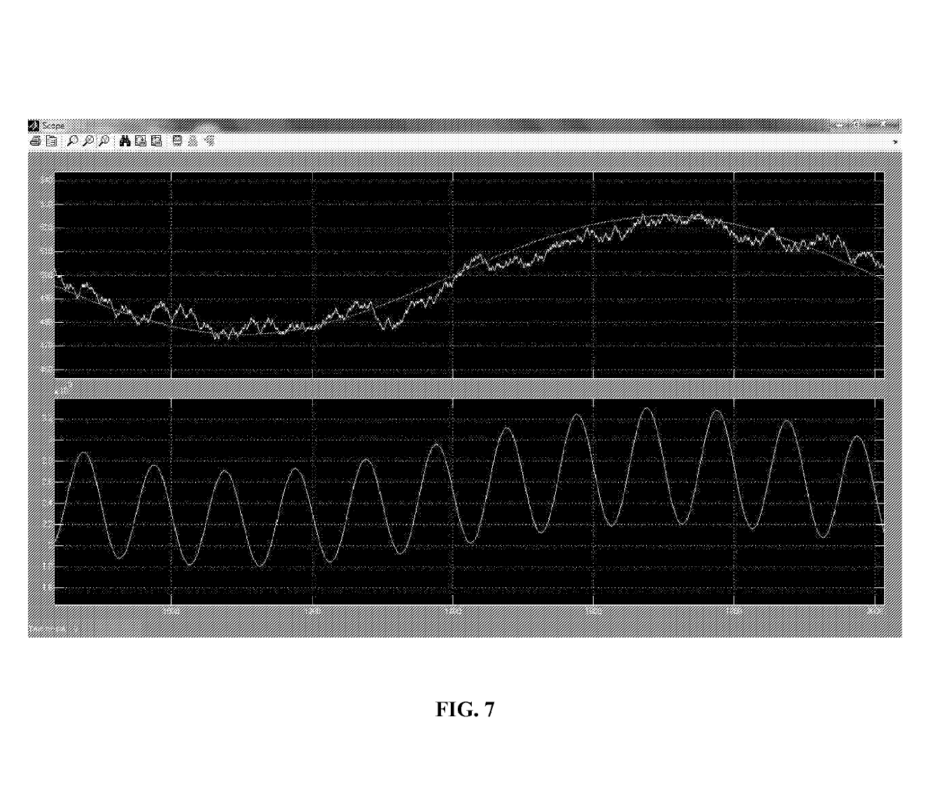

FIG. 7 is a graph illustrating the performance of a tracking procedure, such as the tracking procedure 300 described in relation to FIG. 3. PV generator transients are simulated to include fast transients such as, for example, moving clouds, and slow transients, such as, for example, thermal effects. The generator simulated can be one that can produce up to 340 kW with a maximum power point voltage of around 520V. The upper waveforms (in the upper box) of FIG. 7 shows the behavior of Vmppt(t) (the smooth line) and actual Vpv(t) in Volts. Vmppt(t) is the “ideal” position of the maximum power point voltage and Vpv(t) is the achieved PV voltage. The time axis is provided in seconds. A tracking achieves good performance if the achieved PV voltage closely matches the maximum power point voltage. The lower waveform (lower box) of FIG. 7 shows the harvested power from the PV generator in Watts. The graph shows that the PV power has some large and relatively fast transients. Those transients may be the result of cloud movements. As can be seen from the top graph, in such dynamic conditions the difference between the maximum power point voltage and the actual PV voltage are within +/−5V.

Although solar energy is discussed in relation to the above implementations, the system, methods and all other implementations discussed above can also be used and applied in relation to other types of generators and for other forms of energy, such as energy harvested in wind generators and water pumps.

While particular embodiments have been disclosed herein in detail, this has been done by way of example for purposes of illustration only, and is not intended to be limiting with respect to the scope of the appended claims, which follow. In particular, it is contemplated that various substitutions, alterations, and modifications may be made without departing from the spirit and scope of the invention as defined by the claims. Other aspects, advantages, and modifications are considered to be within the scope of the following claims. The claims presented are representative of the embodiments and features disclosed herein. Other unclaimed embodiments and features are also contemplated. Accordingly, other embodiments are within the scope of the following claims.

What is claimed is:

1. A method for power tracking, the method comprising:
measuring a plurality of samples of power produced by a photovoltaic (PV) array over a first interval of time;
determining, based on the measured plurality of samples of the power of the PV array, a non-linear predictive model of a behavior of the power produced by the PV array;
performing a first adjustment of the PV array's voltage at a second time instant subsequent to an end of the first interval of time;
measuring at a third time instant another sample of the power of the PV array with the adjusted voltage; and
determining a power difference between the power of the PV array with the adjusted voltage at the third time instant and a computed power level of the PV array at the third time instant determined from the non-linear predictive model.

2. The method of claim 1, further comprising:
performing another adjustment of the voltage of the PV array based on the determined power difference between the power of the PV array with the adjusted voltage at the third time instant and the computed power level of the PV array at the third time instant determined from the non-linear predictive model.

3. The method of claim 2, wherein performing the other adjustment of the voltage of the PV array comprises:
increasing the voltage of the PV array in response to a determination that the power difference is greater than ε when the first adjustment of the voltage of the PV array was a voltage increase, wherein ε is a pre-determined value smaller than power produced by the PV array.

4. The method of claim 2, wherein performing the other adjustment of the voltage of the PV array comprises:
decreasing the voltage of the PV array in response to a determination that the power difference is less than ε when the first adjustment of the voltage of the PV array was a voltage increase, wherein ε is a pre-determined value smaller than power produced by the PV array.

5. The method of claim 1, wherein determining the non-linear predictive model of the behavior of the power produced by the PV array comprises:
deriving the non-linear predictive model using one or more of: interpolation polynomials, a least square technique, and trigonometric interpolation.

6. The method of claim 1, wherein measuring the plurality of samples the power of the array over the first interval of time comprises:
measuring the plurality of samples at irregular time periods during the first interval of time.

7. The method of claim 1, wherein the non-linear predictive model of the behavior of the power of the PV array includes a non-linear predictive model of the behavior of the power of the PV array resulting from insolation changes.

8. The method of claim 7, wherein the insolation changes include one or more of: a temperature change, a cloud cover change, and a sun position change.

9. A system comprising:
one or more photovoltaic (PV) arrays configured to convert solar irradiation into current;
a sampling subsystem to measure one or more samples of power produced by the one or more PV arrays; and
a controller configured to:
determine, based on a plurality of samples of the power of the one or more PV array measured over a first time interval, a non-linear predictive model of a behavior of the power produced by the one or more PV arrays,
cause a first adjustment of the one or more PV arrays' voltage at a second time instant subsequent to an end of the first time interval, and
determine a power difference between another sample of the power of the one or more PV arrays with the adjusted voltage measured at a third time instant and a computed power level of the one or more PV arrays at the third time instant determined from the non-linear predictive model.

10. The system of claim 9, wherein the controller is further configured to:
cause another adjustment of the voltage of the one or more PV arrays based on the determined power difference between the power of the one or more PV arrays with the adjusted voltage at the third time instant and the computed power level of the one or more PV arrays at the third time instant determined from the non-linear predictive model.

11. The system of claim 10, wherein the controller configured to cause the other adjustment of the voltage of the one or more PV arrays is configured to:
cause an increase of the voltage of the one or more PV arrays in response to a determination that the power difference is greater than ε when the first adjustment of the voltage of the one or more PV arrays was a voltage increase, wherein ε is a pre-determined value smaller than power produced by the one or more PV arrays.

12. The system of claim 10, wherein the controller configured to cause the other adjustment of the voltage of the one or more PV arrays is configured to:
cause a decrease of the voltage of the PV array in response to a determination that the power difference is less than ε when the first adjustment of the voltage of the one or more PV arrays was a voltage increase, wherein ε is a pre-determined value smaller than power produced by the one or more PV arrays.

13. The system of claim 9, wherein the controller configured to determine the non-linear predictive model of the behavior of the power produced by the one or more PV arrays is configured to:
derive the non-linear predictive model using one or more of: interpolation polynomials, a least square technique, and trigonometric interpolation.

14. The system of claim 9, wherein the controller comprises one or more processors.

15. The system of claim 9, wherein the sampling subsystem configured to measure one or more samples of the power produced by the one or more PV arrays is configured to:
measure the plurality of samples at irregular time periods during the first interval of time.

16. The system of claim 9, wherein the non-linear predictive model of the behavior of the power of the one or more PV arrays includes a non-linear predictive model of the behavior of the power of the one or more PV arrays resulting from insolation changes.

17. The system of claim 16, wherein the insolation changes include one or more of: a temperature change, a cloud cover change, and a sun position change.

18. A method for power tracking, the method comprising:
measuring a plurality of samples of power produced by a photovoltaic (PV) array over a first interval of time;
determining, based on the measured plurality of samples of the power of the PV array, a non-linear predictive model of a behavior of the power of the PV array;
performing a first adjustment of the PV array's current at a second time instant subsequent to an end of the first interval of time;
measuring at a third time instant another sample of the power of the PV array with the adjusted current; and
determining a power difference between the power of the PV array with the adjusted current at the third time instant and a computed power level of the PV array at the third time instant determined from the non-linear predictive model.

19. The method of claim 18, further comprising:
performing another adjustment of the current of the PV array based on the determined power difference between the power of the PV array with the adjusted current at the third time instant and the computed power level of the PV array at the third time instant determined from the non-linear predictive model.

20. The method of claim 18, wherein the non-linear predictive model of the behavior of the power of the PV array includes a non-linear predictive model of the behavior of the power of the PV array resulting from insolation changes.

21. A method for power tracking, the method comprising:
measuring a plurality of samples of power produced by a photovoltaic (PV) array over a first interval of time;
determining, based on the plurality of measured samples of the power of the PV array, a linear predictive model of a behavior of the power produced by the PV array, the linear predictive model derived using a least square technique;
performing a first adjustment of the PV array's voltage at a second time instant subsequent to an end of the first interval of time;
measuring at a third time instant another sample of the power of the PV array with the adjusted voltage; and
determining a power difference between the power of the PV array with the adjusted voltage at the third time instant and a computed power level of the PV array at the third time instant determined from the linear predictive model derived using the least square technique.
